(19) United States
(12) Patent Application Publication
(10) Pub. No.: US 2015/0340339 A1
(43) Pub. Date: Nov. 26, 2015

(54) METHOD FOR MANUFACTURING A SEMICONDUCTOR DEVICE

(71) Applicant: Yutaka Sacho, Tokyo (JP)

(72) Inventor: Yutaka Sacho, Tokyo (JP)

(21) Appl. No.: 14/761,545

(22) PCT Filed: Jan. 14, 2014
(86) PCT No.: PCT/JP2014/050405

§ 371 Date: Jul. 16, 2015

(30) Foreign Application Priority Data
Jan. 16, 2013 (JP) 2013-005092

(51) Int. Cl. H01L 25/065; H01L 23/00; H01L 21/78

(52) U.S. Cl. CPC H01L 25/0657; H01L 21/78; H01L 24/81; H01L 24/11; H01L 24/14; H01L 2224/11005

(57) ABSTRACT

In One method for manufacturing a semiconductor device, a conductive bump is formed on the surface of a semiconductor wafer so as to create a first bump opening area, and a dummy bump is formed on the surface of the semiconductor wafer so as to form a second bump opening area. In such a case, the dummy bump is formed such that the total of the first bump opening area and the second bump opening area is a value corresponding to the opening area of a conductive bump of a semiconductor wafer having only the conductive bump, whereby the semiconductor device is manufactured.

### TECHNICAL FIELD

The present invention relates to a method for manufacturing a semiconductor device.

### BACKGROUND

A plurality of semiconductor chips are stacked in order to achieve high density in a semiconductor device. With this kind of semiconductor device, bumps are formed on a semiconductor wafer, the semiconductor wafer is cut into pieces in order to obtain semiconductor chips, and a plurality of semiconductor chips are stacked by connecting the bumps of the semiconductor chips, and a three-dimensional structure is produced (Patent Document 1).

According to a known method, electroplating is used as a method for forming bumps (Patent Document 2).

Furthermore, a through-electrode for connecting internal wiring etc. is connected to the bump, but the through-electrode may also be formed together with the bump (Patent Document 3).

### Patent Documents

### Patent Document 1: JP 11-261000 A

### Patent Document 2: JP 2009-99589 A

### Patent Document 3: JP 2009-295851 A

### SUMMARY OF THE INVENTION

### Problem to be Solved by the Invention

Here, when a bump is formed by means of plating, it is necessary to set suitable plating conditions in order to obtain a plating layer having the required thickness. For example, when a bump is formed by means of electroplating, the plating thickness depends on the current density (current/bump opening area) during plating.

With structures such as those in cited documents 1-3, however, the semiconductor wafers have a different number of bumps and different bump opening diameters for each product, so the bump opening area within the wafer is also different for each product. For this reason, it is necessary to vary the plating conditions (current and time) for each product in order to achieve the required plating thickness, and as the number of different product types increases, so the number of different plating conditions increases and this causes a problem in terms of poorer production efficiency.

A method for manufacturing a semiconductor device that makes it possible to achieve constant production efficiency when bumps are formed regardless of the type of product would therefore be desirable.

### Means for Solving the Problem

A first mode of the present invention relates to a method for manufacturing a semiconductor device, the method comprising: (a) forming a first bump on the surface of a first wafer in such a way as to achieve a first bump opening area, and (b) forming a dummy bump on the surface of the first wafer in such a way as to achieve a second bump opening area; and in abovementioned (b), the dummy bump is formed in such a way that the total of the first bump opening area and the second bump opening area is a value corresponding to the first bump opening area of a second wafer, which is another wafer having only the first bump.

### Advantage of the Invention

According to the present invention, it is possible to provide a method for manufacturing a semiconductor device that makes it possible to achieve constant production efficiency when bumps are formed.

### BRIEF DESCRIPTION OF THE FIGURES

FIG. 1 is a plan view showing a semiconductor device 200;

FIG. 2 is an enlargement of the area around a product formation region 203 in FIG. 1;

FIG. 3 is a view in the cross section A-A′ in FIG. 2;

FIG. 4 is a view in cross section of a conduction bump 211;

FIG. 5 is a view in cross section of a dummy bump 213;

FIG. 6 is a plan view showing another semiconductor device 400;

FIG. 7 is a view in cross section showing a semiconductor device 200a;

FIG. 8 is a view in cross section showing a semiconductor wafer 202a;

FIG. 9 is a view in cross section showing a conduction bump 211a in FIG. 8;

FIG. 10 is a view in cross section showing a dummy bump 213a in FIG. 8;

FIG. 11 is a plan view showing a semiconductor device 200b;

FIG. 12 is a view in the cross section A-A′ in FIG. 11;

FIG. 13 is a view in cross section showing a semiconductor wafer 202b;

FIG. 14 is a view in cross section showing a dummy bump 216a in FIG. 13;

FIG. 15 is a view in cross section showing a dummy bump 216b in FIG. 13;

FIG. 16 is a plan view showing a semiconductor device 200c;

FIG. 17 is a view in the cross section A-A′ in FIG. 16;

FIG. 18 is a view in cross section showing a semiconductor wafer 202c; and

FIG. 19 is a view in the cross section A-A′ in FIG. 16 (variant example).

### MODE OF EMBODIMENT OF THE INVENTION

A preferred mode of embodiment of the present invention will be described in detail below with reference to the figures.

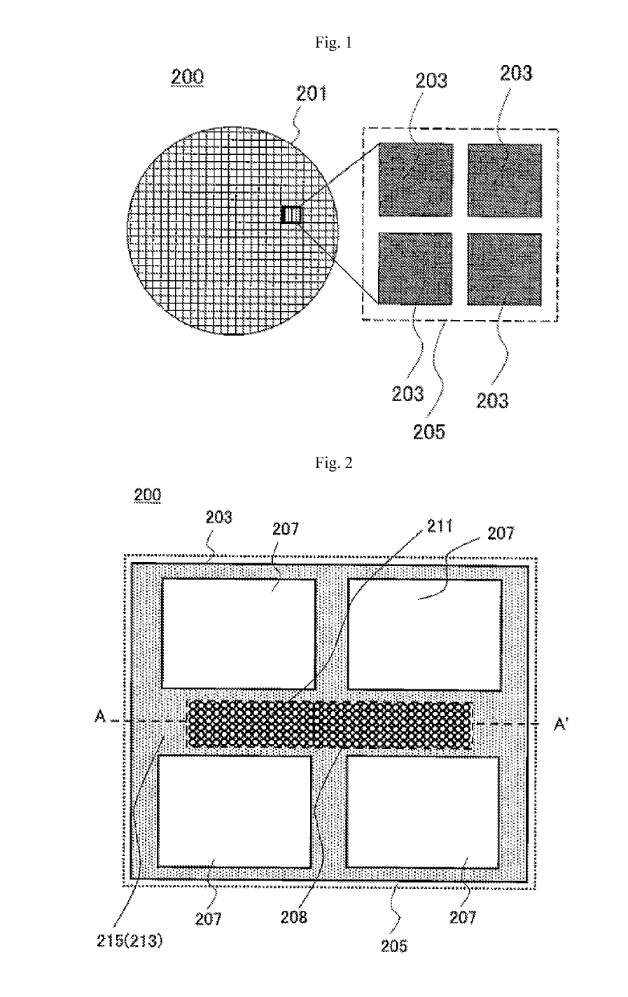

The outline structure of a semiconductor device 200 according to a first mode of embodiment of the present invention will be described first of all with reference to FIG. 1 to FIG. 5.

Here, a semiconductor memory in which a memory chip is mounted will be given as an example of the semiconductor device 200.

As shown in FIG. 1, the semiconductor device 200 comprises a semiconductor wafer 201 serving as a first wafer.

The semiconductor wafer 201 comprises rectangular product formation regions 203 each forming a semiconductor chip, and a scribe region 205 which is provided between the product formation regions 203 and constitutes a lattice-shaped region which is cut when the product formation regions 203 are formed.

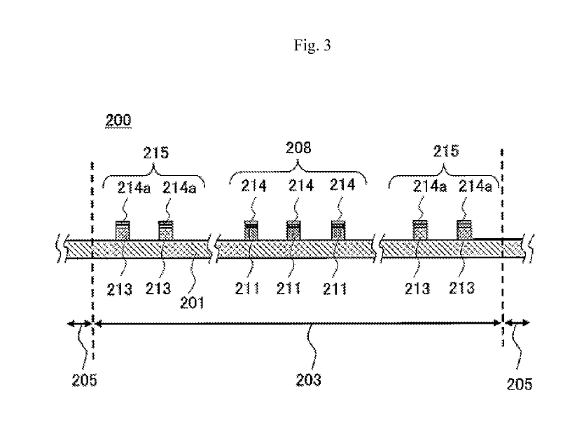

As shown in FIG. 2 and FIG. 3, the product formation regions 203 comprise: memory arrays 207, a conduction bump 211 serving as a first bump that can conduct with the memory arrays 207 and internal wiring or the like (to be described later), and a dummy bump 213 which does not conduct with the memory arrays 207 or the internal wiring etc. (not depicted) (conduction for operation of at least the product formation region 203 is not essential).

The conduction bump 211 is disposed in a conduction bump region 208 between the memory arrays 207 within the product formation region 203, and the dummy bump 213 is provided in a dummy bump region 215 which is a region outside the conduction bump region 208 and the memory arrays 207 within the product formation region 203.

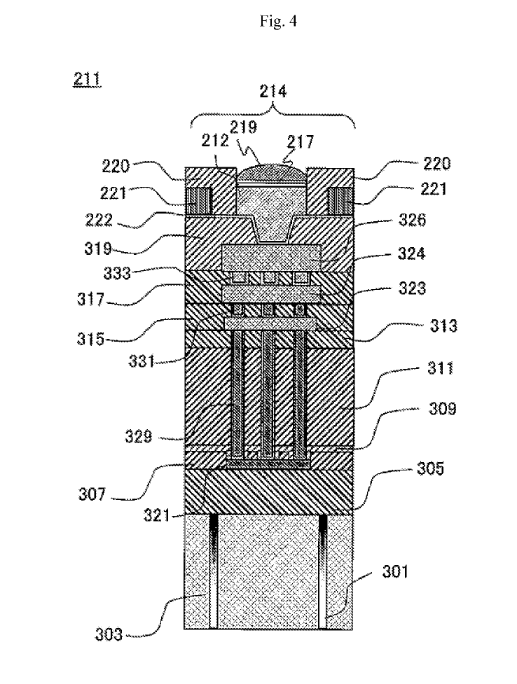

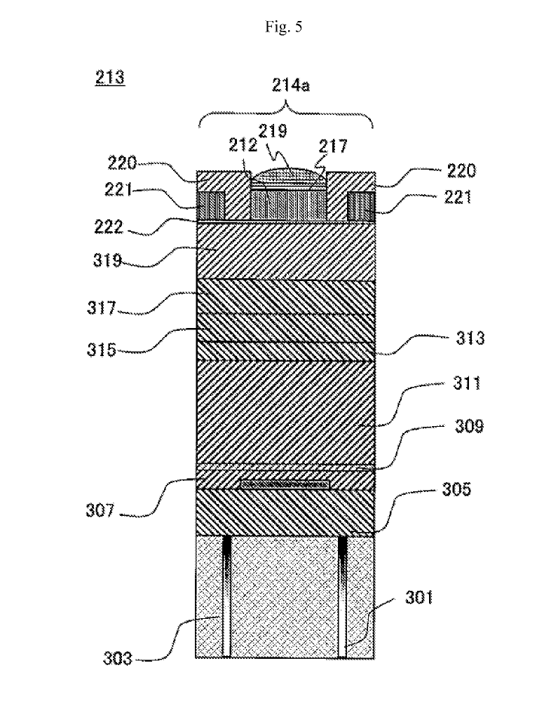

As shown in FIG. 4, the conduction bump 211 has a surface bump 214 which is exposed at the surface of the product formation region 203, and has, in succession from the surface of the product formation region 203, a Cu plating section 212, an Ni plating section 217 and an Au plating section 219.

It should be noted that FIG. 4 shows a resist 220 and a PIQ 221 (polyimide-iso-indroquinazolinedione) around the conduction bump 211.

Meanwhile, the semiconductor wafer 201 has a structure in which the following are stacked: a silicon substrate 303 in which a TSV (Through Substrate Via) trench 301 is formed; a first interlayer insulating film 305; a second interlayer insulating film 307; a stopper silicon nitride film 309; a cylinder interlayer insulating film 311; a third interlayer insulating film 313; a fourth interlayer insulating film 315; a fifth interlayer insulating film 317; and a SiON protective film 319.

Meanwhile, a bit line 321 of the memory array 207 is provided on the first interlayer insulating film 305, first aluminum wiring 323 is provided on the third interlayer insulating film 313, second aluminum wiring 324 is provided on the fourth interlayer insulating film 315, third aluminum wiring 326 is provided on the fifth interlayer insulating film 317, and the third aluminum wiring 326 is connected to the surface bump 214 with a Cu/Ti layer 222 interposed.

Furthermore, the bit line 321 and the first aluminum wiring 323 are connected by a first tungsten plug 329, the first aluminum wiring 323 and the second aluminum wiring 324 are connected by a second tungsten plug 331, and the second aluminum wiring 324 and the third aluminum wiring 326 are connected by a conduction plug 333.

The (surface bump 214 of) the conduction bump 211 can therefore conduct with the first aluminum wiring 323, second aluminum wiring 324 and third aluminum wiring 326, which constitute the internal wiring, and can also conduct with the memory arrays 207 via the bit line 321.

Meanwhile, as shown in FIG. 5, although the dummy bump 213 has a dummy surface bump 214 having the same structure as the conduction bump 211, the dummy surface bump 214a is not connected to the internal wiring or bit line 321.

Here, in the semiconductor device 200, the total of the opening area of the conduction bump 211 (first bump opening area) and the opening area of the dummy bump 213 (second bump opening area) is a value corresponding to the opening area of a conduction bump 411 in another semiconductor device 400 shown in FIG. 6.

To be more specific, the semiconductor device 400 comprises, in the same way as the semiconductor device 200: a semiconductor wafer 402 serving as a second wafer; a product formation region 403 provided within the semiconductor wafer 402; memory arrays 407 provided within the product formation region 403; and a conduction bump 411 which is provided within the product formation region 403 and can conduct with the memory arrays 407 and the internal wiring etc., but the dummy bump 213 is not provided (in terms of bumps, only the conduction bump 411 is included as the first bump). Furthermore, the total opening area of the conduction bump 411 is greater than the total opening area of the conduction bump 211.

The total opening area of the conduction bump 211 and the dummy bump 213 in the semiconductor device 200 is thus a value corresponding to the opening area of the conduction bump 211 of the other semiconductor device 400, and the reason for this will be explained below.

As described above, the surface bump 214 of the conduction bump 211 comprises a Cu plating section 202, an Ni plating section 217 and an Au plating section 219 so plating must be carried out when the bump is formed, but different plating conditions need to be set for the plating thickness in the case of semiconductor devices having different numbers of bumps and different bump opening diameters.

Here, the plating thickness depends on the current density (current/opening area) during plating, but as described above, the total opening area of the conduction bump 411 of the semiconductor device 400 is greater than the total opening area of the conduction bump 211 of the semiconductor device 200, so if the dummy bump 213 is not provided, it is necessary to vary the plating conditions (current and time) between the semiconductor device 200 and the semiconductor device 400 in order to achieve the required plating thickness.

However, if the plating conditions are varied in this way for each product, then as the number of different product types increases, so the number of different plating conditions increases and this causes a problem in terms of poorer production efficiency.

Therefore, when the semiconductor device 200 is manufactured, the dummy bump 213 is provided in addition to the conduction bump 211, the dummy bump 213 being formed in such a way that the total of the opening area of the conduction bump 211 and the opening area of the dummy bump 213 of the semiconductor device 200 corresponds to (in this case is equal to) the opening area of the conduction bump 411 of the other semiconductor device 400.

As a result, it is possible to make the bump opening areas of the semiconductor device 200 and semiconductor device 400 equal, and the semiconductor device 200 and the semiconductor device 400 can be plated under the same plating conditions, so it is possible to achieve constant production efficiency when the bumps are formed, regardless of the type of product.

According to the first mode of embodiment, the semiconductor wafer 201 of the semiconductor device 200 thus comprises the conduction bump 211 and the dummy bump 213, and when the semiconductor device 200 is manufactured, the dummy bump 213 is formed in such a way that the total of the opening area of the conduction bump 211 and the opening area of the dummy bump 213 corresponds to the opening area of the conduction bump 411 of the other semiconductor device 400.

The semiconductor device 200 and the semiconductor device 400 can therefore be plated under the same plating conditions and it is possible to achieve constant production efficiency when the bumps are formed regardless of the type of product.

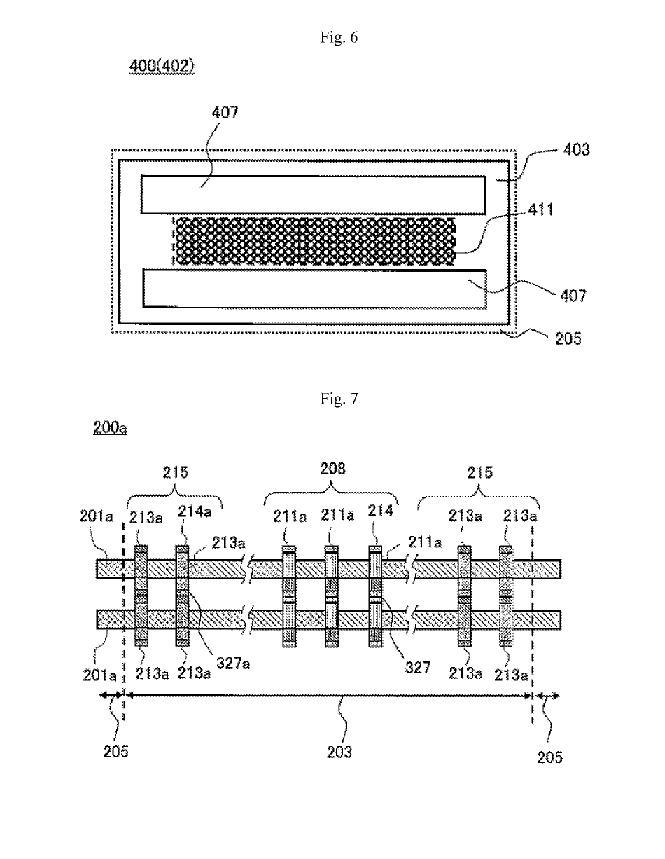

A second mode of embodiment will be described next with reference to FIG. 7 to FIG. 10.

In the second mode of embodiment, which is in accordance with the first mode of embodiment, a semiconductor device 200a is manufactured by stacking a plurality of semiconductor chips 201a using a surface bump 214 and a rear-surface bump 327.

It should be noted that in the second mode of embodiment, elements having the same function as in the first mode of embodiment bear the same reference symbols and the description will focus mainly on portions which are different than the first mode of embodiment.

As shown in FIG. 7, the semiconductor device 200a according to the second mode of embodiment has a structure in which a plurality of semiconductor chips 201a are stacked.

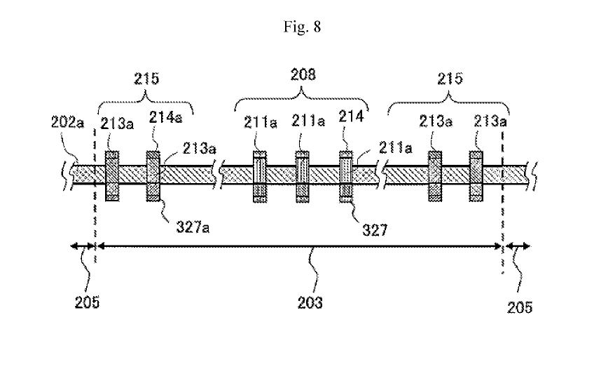

Specifically, the semiconductor chips 201a are chips which are obtained by cutting a semiconductor wafer 202a shown in FIG. 8 into pieces, and are connected using a conduction bump 211a and a dummy bump 213a.

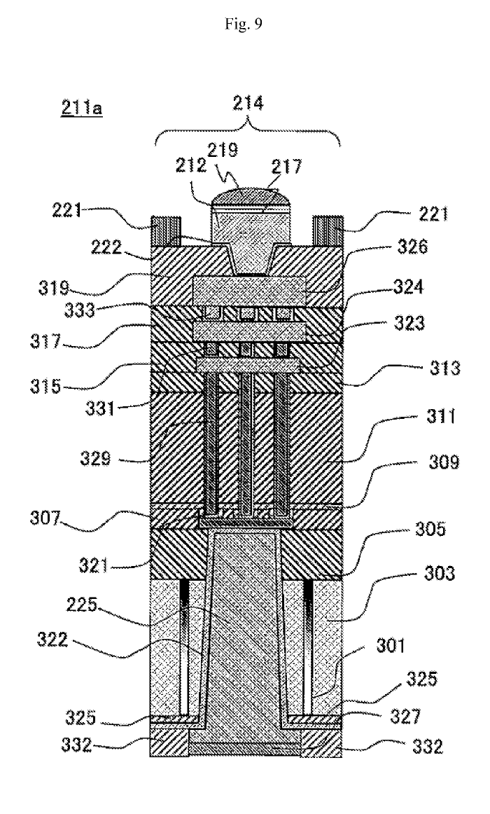

As shown in FIG. 9, the conduction bump 211a of the semiconductor wafer 202a comprises a through-electrode 225 such as Cu which runs through a silicon substrate 303 and a first interlayer insulating film 305 and is connected to a bit line 321 (in other words, is provided inside the semiconductor wafer 202a).

The contact surface between the side surface of the through-electrode 225 and the bit line 321 is covered by a diffusion-prevention layer 322 such as Cu/Ti or the like, and a rear-surface nitride film 325 is provided between the surfaces of the diffusion-prevention layer 322 and the silicon substrate 303.

Furthermore, a rear-surface bump 327 such as Sn/Ag connected to the surface bump 214 of another semiconductor device 200a is provided on the exposed surface of the through-electrode 225 on the silicon substrate 303 side (i.e., on the rear surface of the semiconductor wafer 202a). It should be noted that FIG. 9 also shows a resist 332 provided around the rear-surface bump 327.

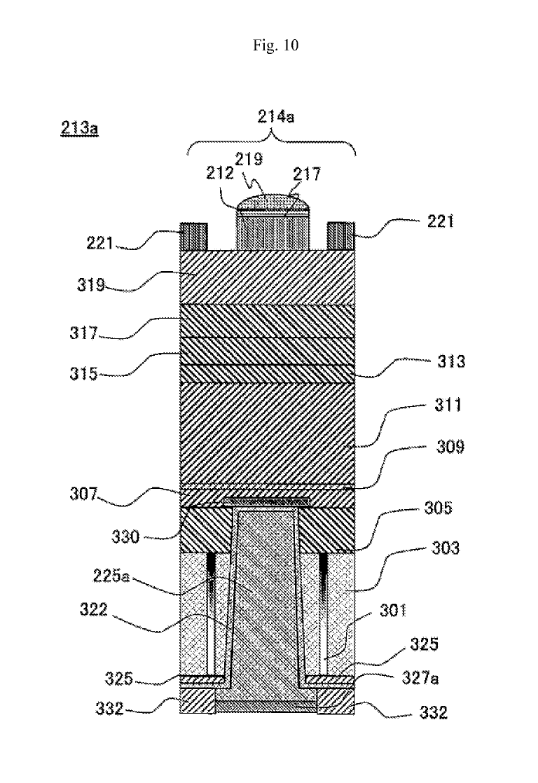

Meanwhile, as shown in FIG. 10, the dummy bump 213a comprises, in the same way as the conduction bump 211a, a dummy through-electrode 225a (having the same structure as the conduction electrode 225), a diffusion-prevention layer 322 and a rear-surface nitride film 325, and also comprises a dummy rear-surface bump 327a (having the same structure as the rear-surface bump 327), but the dummy through-electrode 225a is in contact with an electrically-isolated etching stopper layer 330 rather than the bit line 321, and is not connected to the bit line 321 or the internal wiring.

It should be noted that in FIG. 10, the dummy surface bump 214a, dummy through-electrode 225a and dummy rear-surface bump 327a are arranged in a row in the thickness direction of the semiconductor wafer 202a.

A structure such as this is formed by Cu-plating the TSV opening on the bit line (W pad) formed beforehand at the position where the dummy through-electrode 225a is formed, then performing Sn/Ag plating, and forming the rear-surface bump 327 and through-electrode 225 and the dummy rear-surface bump 327a and dummy through-electrode 225a.

The conduction bump 211a and the dummy bump 213a may thus each have a structure comprising a rear-surface bump 327 and a dummy rear-surface bump 327a.

With this structure, a plurality of semiconductor chips 201a are obtained by cutting the semiconductor wafer 202a into pieces, and as shown in FIG. 7, one surface bump 214 and another rear-surface bump 327, and one dummy surface bump 214a and one dummy rear-surface bump 327a of the semiconductors chip 201a are connected by solder or the like (in other words, the surface of one semiconductor chip 201a is stacked with the rear surface of another semiconductor chip 201a), whereby the semiconductor chips 201a are stacked one on top of the other, and the Au plating section 219 is connected to a substrate which is not depicted, whereby the semiconductor device 200a having a three-dimensional structure is completed.

In this way, according to the second mode of embodiment, the semiconductor wafer 202a of the semiconductor device 200a comprises a conduction bump 211a and a dummy bump 213a, and when the semiconductor device 200a is manufactured, the dummy bump 213a is formed in such a way that the total of the opening area of the conduction bump 211 and the dummy bump 213a constitutes the opening area of the conduction bump 411 of the other semiconductor device 400. The same advantage as in the first mode of embodiment is therefore exhibited.

Furthermore, according to the second mode of embodiment, the semiconductor wafer 202a comprises the conduction bump 211a having the surface bump 214 and the rear-surface bump 327, and the dummy bump 213a having the dummy surface bump 214a and the dummy rear-surface bump 327a.

It is therefore possible to produce a three-dimensional structure for the semiconductor device 200a by stacking a plurality of semiconductor chips 201a obtained by cutting the semiconductor wafer 202a into pieces.

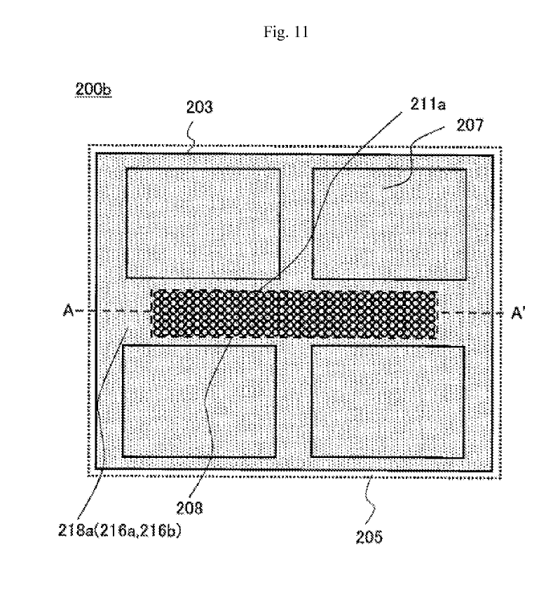

A third mode of embodiment will be described next with reference to FIG. 11 to FIG. 15.

In the third mode of embodiment, which is in accordance with the second mode of embodiment, in terms of dummy bumps, a dummy bump 216a having only a dummy surface bump 214a, and a dummy bump 216b having only a dummy rear-surface bump 327a are provided.

It should be noted that in the third mode of embodiment, elements having the same function as in the second mode of embodiment bear the same reference symbols and the description will focus mainly on portions which are different than the second mode of embodiment.

As shown in FIG. 11, a semiconductor device 200b according to the third mode of embodiment has a conduction bump region 208 and a dummy bump region 218a, but the dummy bump region 218a is also provided in the region in which memory arrays 207 are provided.

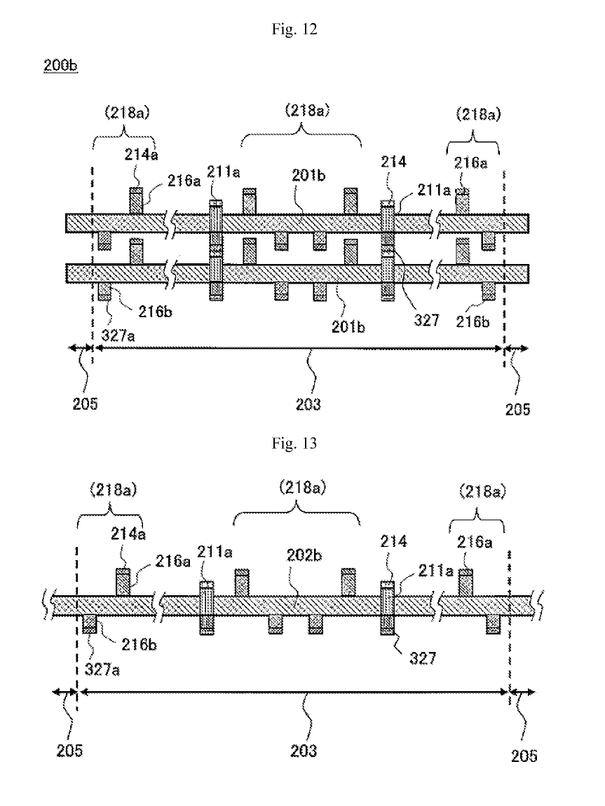

As shown in FIG. 12, the semiconductor device 200b comprises the dummy bump 216a having only the dummy surface bump 214a, and the dummy bump 216b having only the dummy rear-surface bump 327a, the dummy bump 216a and the dummy bump 216b being provided in such a way that the planar positions thereof are offset from one another.

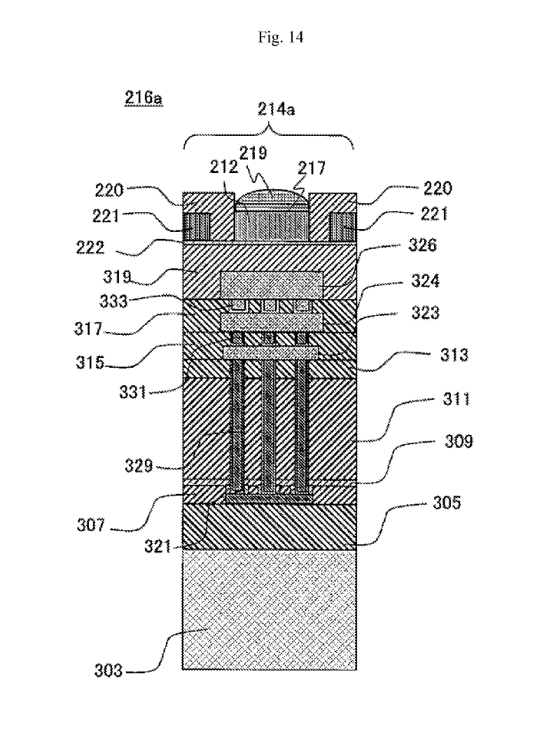

Furthermore, the semiconductor chips 201b are connected by means of the conduction bump 211a rather than by the dummy bump 216a and the dummy bump 216b. It should be noted that the semiconductor chips 201b are obtained by cutting the semiconductor wafer 202b shown in FIG. 13 into pieces.

As shown in FIG. 14, the dummy bump 216a of the semiconductor wafer 202b has only the dummy surface bump 214a, and even if the dummy surface bump 214a is disposed above the first aluminum wiring 323, second aluminum wiring 324, third aluminum wiring 326 and bit line 321, it is not connected thereto.

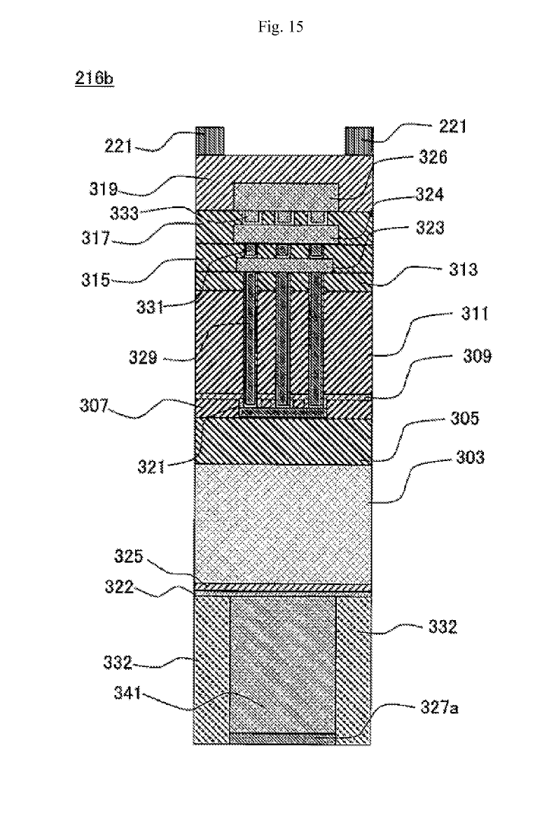

Meanwhile, as shown in FIG. 15, the dummy bump 216b of the semiconductor wafer 202b comprises: a rear-surface nitride film 325 provided on the rear surface of a silicon substrate 303; a diffusion-prevention layer 322 formed on the rear-surface nitride film 325; and a dummy-rear surface bump 327a provided on the diffusion-prevention layer 322 (i.e., on the rear surface of the semiconductor wafer 202b). The dummy rear-surface bump 327a is provided with the interposition of a Cu layer 341 provided on the diffusion-prevention layer 322.

With this configuration also, even if the dummy rear-surface bump 327a is disposed below the first aluminum wiring 323, second aluminum wiring 324, third aluminum wiring 326 and bit line 321, it is not connected thereto.

In this way, it is not necessarily essential to provide both the dummy surface bump 214a and the dummy rear-surface bump 327a for the dummy bumps.

By virtue of a configuration such as this, the positions in which the dummy surface bump 214a and dummy rear-surface bump 327a are placed may be offset (staggered). With a structure such as this, when the semiconductor device 200b is manufactured, the semiconductor wafer 202b is cut into pieces to obtain semiconductor chips 201b and the semiconductor chips 201b may be stacked in such a way that the dummy bump 216a and the dummy bump 216b are not in contact, as shown in FIG. 12.

Even if the dummy bumps 216a, 216b and the conduction bump 211 have different heights, the semiconductor chips 201b can therefore be connected together. Furthermore, by virtue of a structure having only the dummy surface bump 214a or the dummy rear-surface bump 327a (a structure which is not provided with a through-electrode), the dummy bumps 216a, 216b may be provided on the surface (or rear surface) of the memory arrays 207.

In this way, according to the third mode of embodiment, the semiconductor wafer 202b of the semiconductor device 200b comprises the conduction bump 211a and the dummy bumps 216a, 216b, and is manufactured by forming the dummy bumps 216a, 216b in such a way that the total of the opening areas of the conduction bump 211a and the dummy bumps 216a, 216b constitutes the opening area of the conduction bump 411 of the other semiconductor device 400. The same advantage as in the second mode of embodiment is therefore exhibited.

Furthermore, according to the third mode of embodiment, the semiconductor wafer 202b of the semiconductor device 200b is provided in such a way that the dummy bump 216a having only the dummy surface bump 214a, and the dummy bump 216b having only the dummy rear-surface bump 327a are offset from each other, and when the semiconductor device 200b is manufactured, the wafer 202b is cut into pieces in order to obtain the semiconductor chips 201b, and the semiconductor chips 201b are stacked in such a way that the dummy bump 216a and the dummy bump 216b are not in contact.

Even if the dummy bumps 216a, 216b and the conduction bump 211a have different heights, the semiconductor chips 201b can therefore be connected together. Furthermore, the dummy bumps 216a, 216b may be provided on the surface (or rear surface) of the memory arrays 207.

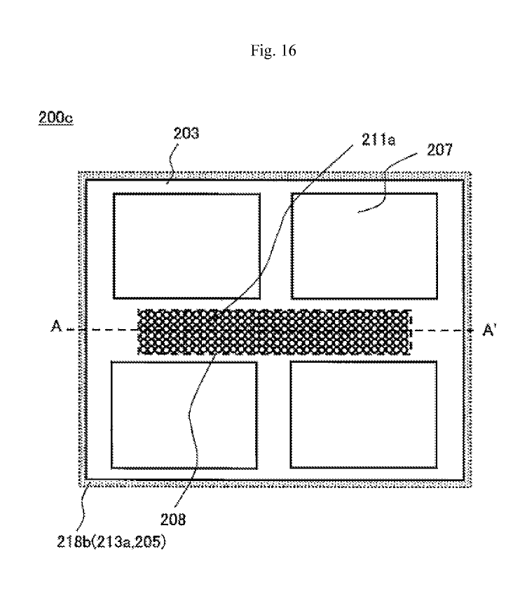

A fourth mode of embodiment will be described next with reference to FIG. 16 to FIG. 19.

In the fourth mode of embodiment, which is in accordance with the second mode of embodiment, a dummy bump region 218a is provided in a scribe region 205.

It should be noted that in the fourth mode of embodiment, elements having the same function as in the second mode of embodiment bear the same reference symbols and the description will focus mainly on portions which are different than the second mode of embodiment.

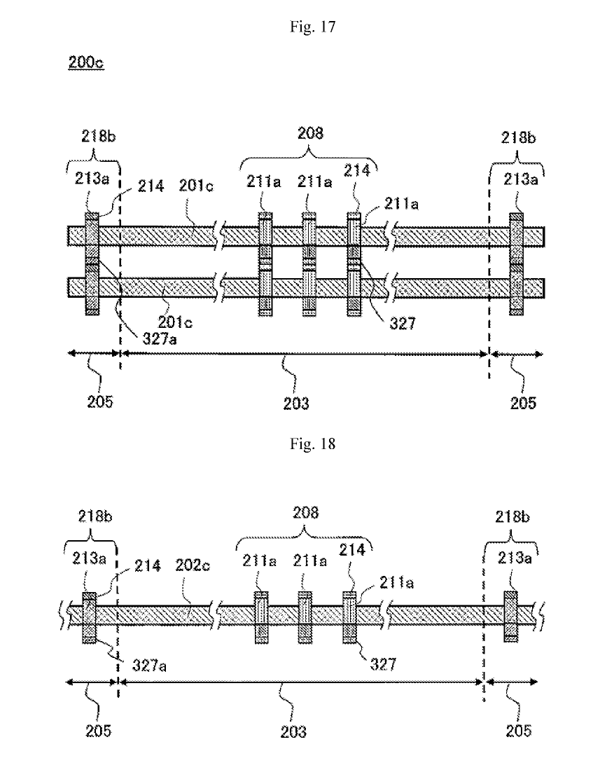

As shown in FIG. 16 and FIG. 17, a semiconductor chip 201c of a semiconductor device 200c according to the fourth mode of embodiment has a dummy bump region 218b which is provided in a scribe region 205, and a dummy bump 213a is provided in the scribe region 205. It should be noted that the semiconductor chip 201c is obtained by cutting the semiconductor wafer 202c shown in FIG. 18 into pieces.

In this way, the dummy bump region 218b may be provided in the scribe region 205.

By virtue of this kind of configuration, there is no longer any need to provide the dummy bump 213a within a product formation region 203, so it is possible to prevent a reduction in the mounting region within the product formation region 203 caused by providing the dummy bump 213a.

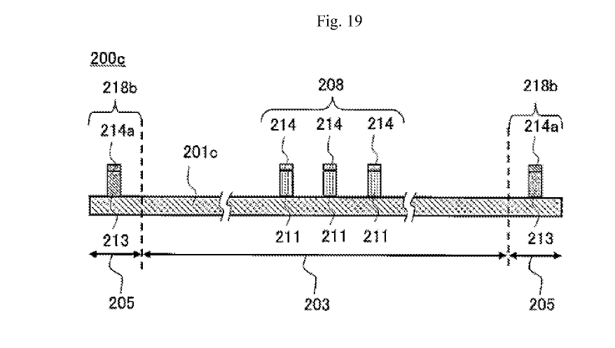

It should be noted that FIG. 17 shows an exemplary case employing a conduction bump 211a having a through-electrode 225, and a dummy bump 213a having a through-electrode 225a, but as shown in FIG. 19, it is equally possible to provide a conduction bump 211 having only a surface bump 214, and a dummy bump 213 having only a dummy surface bump 214a.

In this way, according to the fourth mode of embodiment, the semiconductor wafer 202c of the semiconductor device 200c comprises the conduction bump 211a and the dummy bump 213a, and is manufactured by forming the dummy bump 213a in such a way that the total of the opening areas of the conduction bump 211 and the dummy bump 213a constitutes the opening area of the conduction bump 211a of the other semiconductor device 400.

Furthermore, according to the fourth mode of embodiment, when the semiconductor device 200c is manufactured, the dummy bump region 218a is provided in the scribe region 205.

It is therefore possible to prevent a reduction in the mounting region within the product formation region 203 caused by providing the dummy bump 218a.

### INDUSTRIAL APPLICABILITY

The present invention devised by the present inventor was described above on the basis of a mode of embodiment and exemplary embodiments, but the present invention is not limited to the exemplary embodiments and it goes without saying that various modifications may be made within a scope that does not depart from the essential point of the present invention.

It should be noted that the present application is based on and claims the benefit of priority to Japanese Patent Application 2013-5092 filed on Jan. 16, 2013, the disclosure of which is incorporated herein in its entirety as a reference document.

### KEY TO SYMBOLS

200: Semiconductor device
200a: Semiconductor device
200b: Semiconductor device
200c: Semiconductor device
201: Semiconductor wafer
201a: Semiconductor chip
201b: Semiconductor chip
201c: Semiconductor chip
202a: Semiconductor wafer
202b: Semiconductor wafer
202c: Semiconductor wafer
203: Product formation region
205: Scribe region
207: Memory array
208: Conduction bump region
211: Conduction bump
211a: Conduction bump
212: Cu plating section
213: Dummy bump
213a: Dummy bump
214: Surface bump
214a: Dummy surface bump
215: Dummy bump region
216a: Dummy bump
216b: Dummy bump
217: Ni plating section
218a: Dummy bump region
218b: Dummy bump region
219: Au plating section
220: Resist
221: PIQ
222: Cu/Ti layer
225: Through-electrode
225a: Dummy through-electrode
301: TSV trench
303: Silicon substrate
305: First interlayer insulating film
307: Second interlayer insulating film
309: Stopper silicon nitride film
311: Cylinder interlayer insulating film
313: Third interlayer insulating film
315: Fourth interlayer insulating film
317: Fifth interlayer insulating film
319: SiON protective film
321: Bit line
322: Diffusion-prevention layer
323: First aluminum wiring
324: Second aluminum wiring
325: Rear-surface nitride film
326: Third aluminum wiring
327: Rear-surface bump
327a: Dummy rear-surface bump
329: First tungsten plug
330: Etching stopper layer
331: Second tungsten plug
332: Resist
333: Conduction plug
341: Cu layer
400: Semiconductor device
402: Semiconductor wafer
403: Product formation region
407: Memory array
411: Conduction bump

1. A method for manufacturing a semiconductor device, the method comprising:
forming a first bump on the surface of a first wafer in such a way as to achieve a first bump opening area, and
forming a dummy bump on the surface of the first wafer in such a way as to achieve a second bump opening area;
wherein forming the dummy bump comprises forming the dummy bump in such a way that the total of the first bump opening area and the second bump opening area is a value corresponding to the first bump opening area of a second wafer, which is another wafer having only the first bump.

2. The method of claim 1, wherein forming the dummy bump comprises:
forming a surface dummy bump on the surface of the first wafer;
forming a rear-surface dummy bump on the rear surface of the first wafer; and
connecting a dummy through-electrode to the rear-surface dummy bump, wherein the dummy through-electrode is inside the first wafer, and wherein the surface dummy bump, the rear-surface dummy bump, and the dummy through-electrode are arranged in a row in the thickness direction of the first wafer.

3. The method of claim 1, wherein the first wafer is cut into pieces in order to obtain a plurality of first chips, and the plurality of first chips are stacked.

4. The method of claim 3, wherein the surface of one first chip is stacked with the rear surface of another first chip.

5. The method of claim 1, wherein forming the dummy bump comprises forming a surface dummy bump on the surface of the first wafer.

6. The method of claim 1, wherein forming the dummy bump comprises forming a rear-surface dummy bump on the rear surface of the first wafer.

7. The method of claim 5, wherein forming the dummy bump comprises:
forming a surface dummy bump on the surface of the first wafer; and
forming a rear-surface dummy bump on the rear surface of the first wafer, wherein the surface dummy bump and the rear-surface dummy bump are arranged in such a way that the planar positions of the surface dummy bump and the rear-surface dummy bump are offset.

8. The method of claim 7, wherein the first wafer is cut into pieces in order to obtain first chips, and the first chips are stacked in such a way that the surface dummy bump and the rear-surface dummy bump do not come into contact.

9. The method of claim 1, wherein the first wafer comprises:
a plurality of product formation regions and
a scribe region which is provided between the plurality of product formation regions and serves to separate the plurality of product formation regions;
wherein forming the dummy bump comprises disposing the first bump in the product formation region and disposing the dummy bump in the scribe region.
